(19) United States
(12) Patent Application Publication
(10) Pub. No.: US 2024/0332435 A1
(43) Pub. Date: Oct. 3, 2024

(54) COVER MEMBER AND SOLAR CELL

(71) Applicant: AGC Inc., Tokyo (JP)

(72) Inventor: Shimpei MORITA, Tokyo (JP)

(73) Assignee: AGC Inc., Tokyo (JP)

(21) Appl. No.: 18/735,281

(22) Filed: Jun. 6, 2024

Related U.S. Application Data
(63) Continuation of application No. PCT/JP2022/046553, filed on Dec. 16, 2022.

(30) Foreign Application Priority Data
Dec. 22, 2021 (JP) 2021-208665

(51) Int. Cl. H01L 31/0203; B64G 1/10; B64G 1/44; H01L 31/041

(52) U.S. Cl. CPC H01L 31/0203; H01L 31/041; B64G 1/10; B64G 1/443

(57) ABSTRACT

The present invention relates to a cover member to be used for a solar cell mounted on an artificial satellite, the cover member including: a transparent base; and an ultraviolet rays cutting layer disposed on the transparent base, in which the transparent base has a thickness of 0.2 mm or less, and the cover member has a transmittance of 3% or less at a wavelength of 300 nm, and an average transmittance of 85% or more at a wavelength of 400 nm to 800 nm.

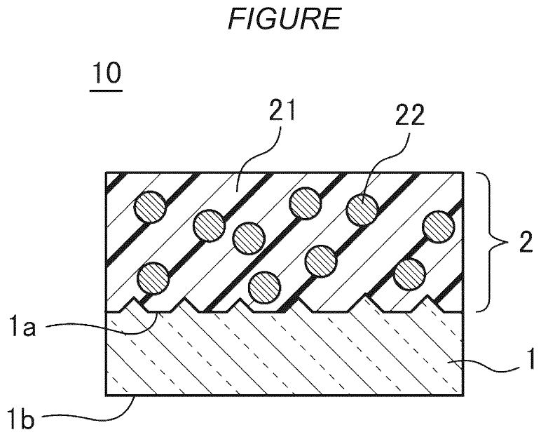

### TECHNICAL FIELD

The present invention relates to a cover member used in a solar cell and a solar cell including the cover member.

### BACKGROUND ART

A cover member is used for a solar cell mounted on an artificial satellite to provide durability to the solar cell. From the viewpoint of reducing a weight of the solar cell, it is desired to use a relatively thin glass as the cover member. In order to maintain power generation efficiency, the cover member of the solar cell is required to satisfactorily transmit mainly light in a visible range.

The outside of the stratosphere is irradiated with deep ultraviolet rays (UV-C) that do not reach the ground. Irradiation with the deep ultraviolet rays leads to deterioration of the solar cell, and therefore, when the solar cell is mounted on the artificial satellite, it is also required to protect the solar cell from the deep ultraviolet rays with the cover member. However, when a general glass or the like is made thinner to reduce the weight thereof, a transmittance of deep ultraviolet rays increases, which may be insufficient to protect the solar cell.

In this regard, Patent Literature 1 discloses a glass for a solar cell cover having a predetermined glass composition containing cerium oxide (CeO₂) and the like, and describes that the cover glass for a solar cell has an ultraviolet rays shielding ability and is excellent in transmittance from near infrared to visible light region.

### CITATION LIST

### Patent Literature

Patent Literature 1: JPS62-187141A

### SUMMARY OF INVENTION

### Technical Problem

However, when specific components are added to the glass composition in order to prevent the transmission of deep ultraviolet rays, raw materials for the glass become expensive and productivity may be degraded. In addition, demand for the cover member for a solar cell mounted on an artificial satellite is smaller than that for use as building materials or the like. Therefore, it is not preferable from a commercial point of view to produce a glass by adjusting the glass composition exclusively, and it is desired to satisfy the desired characteristics by using more commonly used glass or the like.

Accordingly, an object of the present invention is to provide a cover member for a solar cell, preferably a cover member for a solar cell mounted on an artificial satellite, that can both be made thinner more easily and have desired transmission performance with no need to prepare a glass having a special composition or the like.

### Solution to Problem

That is, the present invention relates to the following 1 to 14.
1. A cover member to be used for a solar cell mounted on an artificial satellite, the cover member including:
   a transparent base; and
   an ultraviolet rays cutting layer disposed on the transparent base, in which
   the transparent base has a thickness of 0.2 mm or less, and
   the cover member has a transmittance of 3% or less at a wavelength of 300 nm, and an average transmittance of 85% or more at a wavelength of 400 nm to 800 nm.
2. A cover member to be used for a solar cell, the cover member including:
   a transparent base; and
   an ultraviolet rays cutting layer disposed on the transparent base, in which
   the transparent base has a thickness of 0.2 mm or less, and
   the cover member has a transmittance of 3% or less at a wavelength of 300 nm, and an average transmittance of 85% or more at a wavelength of 400 nm to 800 nm.
3. The cover member according to 1 or 2, in which
   the ultraviolet rays cutting layer includes SiO₂ and metal oxide nanoparticles, and
   a metal oxide constituting the metal oxide nanoparticles is one or more selected from the group consisting of zinc oxide, titanium oxide, cerium oxide, iron oxide, and tungsten oxide.
4. The cover member according to 3, in which
   the ultraviolet rays cutting layer includes 10 mass % to 50 mass % of the metal oxide nanoparticles and 20 mass % to 70 mass % of SiO₂, and has a film thickness of 0.2 μm to 2 μm.
5. The cover member according to 1 or 2, in which
   the transparent base has a first main surface and a second main surface facing each other,
   the ultraviolet rays cutting layer is disposed on the first main surface of the transparent base, and
   the first main surface has an uneven structure with a height difference of 1 nm to 50 nm and a surface roughness Ra of 0.3 nm to 3 nm which are measured by an atomic force microscope.
6. The cover member according to 1 or 2, in which
   the transparent base has a first main surface and a second main surface facing each other,
   the ultraviolet rays cutting layer is disposed on the first main surface of the transparent base, and
   the first main surface has an uneven structure with a height difference of 1 nm to 50 nm determined by observing a cross section of the cover member by a scanning electron microscope.
7. The cover member according to 1 or 2, in which
   the transparent base is a glass base.
8. The cover member according to 7, in which
the glass base includes, in terms of mass % based on oxides,
   0.0% to 0.1% of TiO₂, and
   0.0% to 0.1% of CeO₂.
9. The cover member according to 7, in which
the glass base includes, in terms of mass % based on oxides,
   0.0% to 0.1% of TiO₂.
10. The cover member according to 7, in which
   the glass base includes, in terms of mass % based on oxides,
      0.0% to 0.1% of CeO₂.
11. The cover member according to 1 or 2, in which
   the ultraviolet rays cutting layer has a refractive index of 1.5 to 1.8.
12. The cover member according to 1 or 2, having a transmittance of 30% or more at a wavelength of 350 nm.
13. The cover member according to 1 or 2, in which
   an area of a main surface is 1 m² or more, and a length of a long side is 1.5 m or more or a length of a short side is 0.5 m or more.
14. A solar cell to be mounted on an artificial satellite, the solar cell including the cover member according to 1 or 2.

### Advantageous Effects of Invention

The cover member of the present invention includes the transparent base and the ultraviolet rays cutting layer disposed on the transparent base, and by having a specific thickness and transmission performance, the cover member can both be made thinner more easily and have desired transmission performance with no need to prepare a glass having a special composition or the like.

### BRIEF DESCRIPTION OF DRAWINGS

The FIGURE is a cross-sectional view schematically showing a configuration example of a cover member according to an embodiment.

### DESCRIPTION OF EMBODIMENTS

Hereinafter, the present invention will be described in detail, but the present invention is not limited to the following embodiment and can be freely modified and implemented without departing from the gist of the present invention. In addition, the word “to” that is used to express a numerical range includes the numerical values before and after the word as the lower limit value and the upper limit value of the range, respectively. Note that the embodiment described in the drawings is made schematically for the purpose of clearly illustrating the present invention, and does not necessarily accurately represent an actual size or scale.

A cover member of the present invention is used for a solar cell, preferably for a solar cell mounted on an artificial satellite. Hereinafter, in the present specification, a solar cell includes a solar cell mounted on an artificial satellite. The cover member includes a transparent base and an ultraviolet rays cutting layer disposed on the transparent base, in which a thickness of the transparent base is 0.2 mm or less, and the cover member has a transmittance of 3% or less at a wavelength of 300 nm, and an average transmittance of 85% or more at a wavelength of 400 nm to 800 nm.

The FIGURE is a cross-sectional view taken along a thickness direction schematically showing a configuration example of the cover member according to the present embodiment. In the FIGURE, a cover member 10 includes a transparent base 1 and an ultraviolet rays cutting layer 2 disposed on the transparent base 1. The transparent base 1 has a first main surface 1a and a second main surface 1b facing each other, and the ultraviolet rays cutting layer 2 is disposed on the first main surface 1a of the transparent base 1. Note that although the FIGURE schematically illustrates a case where the first main surface 1a has an uneven structure, which will be described later, the first main surface 1a may be flat.

In the cover member according to the present embodiment, a thickness of the transparent base is 0.2 mm or less, and the cover member has a transmittance of 3% or less at a wavelength of 300 nm, and an average transmittance of 85% or more at a wavelength of 400 nm to 800 nm. The cover member according to the present embodiment includes the transparent base and the ultraviolet rays cutting layer disposed on the transparent base, and by having the thickness and transmission performance described above, the cover member can both be made thinner more easily and have transmission performance required for use in a solar cell with no need to prepare a glass having a special composition. More specifically, since the cover member has performance in cutting deep ultraviolet rays by having a transmittance of 3% or less at a wavelength of 300 nm, the solar cell can be protected when the cover member is used for a solar cell. In addition, since the cover member can transmit light in a visible range satisfactorily by having an average transmittance of 85% or more at a wavelength of 400 nm to 800 nm, a sufficient power generation efficiency can be achieved when the cover member is used for a solar cell.

### (Ultraviolet Rays Cutting Layer)

In the present embodiment, the ultraviolet rays cutting layer is a layer that provides ultraviolet rays cutting performance to the cover member by having ultraviolet rays cutting performance. Here, the ultraviolet rays cutting performance refers to performance of reducing a transmittance for deep ultraviolet rays, and more specifically refers to performance of reducing a transmittance of the cover member at a wavelength of 300 nm. The ultraviolet rays cutting layer is not particularly limited as long as it has the ultraviolet rays cutting performance and can ensure the transmittance in the visible range of the cover member, and for example, the following configuration is preferable.

The ultraviolet rays cutting layer 2 is preferably a layer containing ultraviolet rays absorbing particles 22 in a matrix 21, as shown in the FIGURE. That is, the ultraviolet rays cutting layer 2 absorbs ultraviolet rays by the ultraviolet rays absorbing particles 22 having an ultraviolet rays absorbing ability held in the matrix 21, and therefore becomes a layer having the ultraviolet rays cutting performance.

As the matrix, for example, one that has transmission properties in the visible range when forming the ultraviolet rays cutting layer is suitably used. The matrix itself may not have the ultraviolet rays absorbing ability. Specifically, examples of the matrix include a matrix including SiO₂ as a main component and a matrix including Al₂O₃ as a main component, and from the viewpoint of excellent durability, the matrix including SiO₂ as a main component is preferable. Note that the main component here refers to a component that occupies, for example, 50 mass % or more in the matrix.

The ultraviolet rays absorbing particles are particles that have a function of absorbing ultraviolet rays. Specific examples of the ultraviolet rays absorbing particles include metal oxide nanoparticles, metal sulfide particles, metal selenide particles, and organic ultraviolet rays absorbing particles, and metal oxide nanoparticles are preferable because of excellent weather resistance thereof. Here, nanoparticles mean particles having a particle diameter of, for example, 1 nm to 500 nm. Examples of a metal oxide constituting the metal oxide nanoparticles include zinc oxide, titanium oxide, cerium oxide, iron oxide, and tungsten oxide, and one or more selected from the group consisting of these metal oxides are preferable, and at least one of zinc oxide and titanium oxide is more preferable from the viewpoint of high ultraviolet rays absorbance and low absorbance of visible light transmittance as compared with the ultraviolet rays absorbance. As the ultraviolet rays absorbing particles, one type of the above-mentioned particles may be used alone, or two or more types may be used in combination.

That is, the ultraviolet rays cutting layer contains SiO₂ and metal oxide nanoparticles, and the metal oxide is preferably one or more selected from the group consisting of zinc oxide, titanium oxide, cerium oxide, iron oxide, and tungsten oxide. A composition of the ultraviolet rays cutting layer can be determined by, for example, X-ray electron spectroscopy or energy dispersive X-ray spectroscopy. Specifically, it can be confirmed from X-ray electron spectroscopy and the Fourier transform infrared spectroscopy that the ultraviolet rays cutting layer contains SiO₂, and it can be confirmed by analyzing a scanning electron microscope image of a cross section of a cut film using energy dispersive X-ray spectroscopy that the ultraviolet rays cutting layer contains specific metal oxide nanoparticles. Contents thereof can be confirmed by performing X-ray electron spectroscopy measurement in a film thickness direction of the ultraviolet rays cutting layer.

When the ultraviolet rays cutting layer contains metal oxide nanoparticles, the higher the content ratio of the metal oxide nanoparticles in the ultraviolet rays cutting layer, the more the amount of ultraviolet rays absorbed can be increased. However, metal oxide nanoparticles have a relatively high refractive index, and if the content ratio thereof is excessively high, a light reflectance of the cover member tends to increase. In this case, the transmittance of the cover member in the visible range may become low. From this point of view, it is preferable that the content ratio of metal oxide nanoparticles in the ultraviolet rays cutting layer is equal to or less than a predetermined value.

Moreover, the amount of ultraviolet rays absorbed by the ultraviolet rays cutting layer can be increased not only by increasing the content ratio of metal oxide nanoparticles but also by increasing the film thickness of the ultraviolet rays cutting layer. Therefore, it is also preferable to increase the ultraviolet rays cutting performance by increasing the film thickness while keeping the content ratio of the metal oxide nanoparticles at a predetermined value or less. However, when the main component of the matrix is SiO₂, a coating film forming the matrix shrinks in volume when cured, although it depends on a film forming method. From the viewpoint of preventing peeling of the ultraviolet rays cutting layer due to shrinkage during film formation, it is conceivable to make the film thickness relatively small or to make a content ratio of the SiO₂ precursor which becomes a shrinkage product relatively small in a coating composition before curing. As will be described later, it is also preferable to improve adhesion between the ultraviolet rays cutting layer and the transparent base by a method such as providing a predetermined uneven structure on the main surface of the transparent base.

Considering the above, when the ultraviolet rays cutting layer contains metal oxide nanoparticles, the content (content ratio) of the metal oxide nanoparticles in the ultraviolet rays cutting layer is preferably 10 mass % or more, more preferably 15 mass % or more, and still more preferably 20 mass % or more, to improve the ultraviolet rays cutting performance. On the other hand, in order to prevent a decrease in transmittance in the visible range, the content (content ratio) of metal oxide nanoparticles is preferably 50 mass % or less, more preferably 40 mass % or less, and still more preferably 30 mass % or less. The content (content ratio) of metal oxide nanoparticles in the ultraviolet rays cutting layer may be 10 mass % to 50 mass %.

When the main component of the matrix is SiO₂, the content (content ratio) of SiO₂ in the ultraviolet rays cutting layer is preferably 20 mass % or more, more preferably 30 mass % or more, and still more preferably 40 mass % or more, to improve durability of the film. On the other hand, in order to prevent film peeling, the content (content ratio) of SiO₂ is preferably 70 mass % or less, more preferably 60 mass % or less, and still more preferably 55 mass % or less. The content (content ratio) of SiO₂ in the ultraviolet rays cutting layer may be 20 mass % to 70 mass %.

The film thickness of the ultraviolet rays cutting layer is preferably 0.2 μm or more, more preferably 0.4 μm or more, and still more preferably 0.5 μm or more to improve the ultraviolet rays cutting performance. On the other hand, in order to prevent peeling of the film, the film thickness is preferably 3 μm or less, more preferably 2 μm or less, and still more preferably 1 μm or less. The film thickness of the ultraviolet rays cutting layer may be 0.2 μm to 3 μm. The film thickness of the ultraviolet rays cutting layer can be measured by measuring a level difference created by scratching the ultraviolet rays cutting layer with a stylus type surface profile measuring device.

In order to provide various kinds of performance in a well-balanced manner, it is more preferable that the ultraviolet rays cutting layer contains 10 mass % to 50 mass % of metal oxide nanoparticles, 20 mass % to 70 mass % of SiO₂, and has a film thickness of 0.2 μm to 2 μm.

The refractive index of the ultraviolet rays cutting layer is preferably 1.5 to 1.8, and more preferably 1.5 to 1.7. By setting the refractive index within the above range, a difference in refractive index between the transparent base and the ultraviolet rays cutting layer can be easily reduced, and a decrease in transmittance in the visible range can be prevented. The refractive index of the ultraviolet rays cutting layer can be measured by performing optical constant analysis using a reflection spectroscopic film thickness meter.

In the ultraviolet rays cutting layer, it is preferable that the ultraviolet rays absorbing particles do not protrude from a surface of the ultraviolet rays cutting layer. This can be confirmed from that the ultraviolet rays absorbing particles are covered with the matrix when the surface and a cut cross section of the ultraviolet rays cutting layer are observed with a scanning electron microscope. Since the ultraviolet rays absorbing particles do not protrude from the surface of the ultraviolet rays cutting layer, deterioration of the ultraviolet rays absorbing particles can be prevented. When the ultraviolet rays absorbing particles are metal oxide nanoparticles, other substances that come into contact with the particles may deteriorate. Therefore, deterioration of other substances such as an adhesive layer that may come into contact with the ultraviolet rays cutting layer can be prevented by not allowing the particles to protrude. Examples of a method for preventing the ultraviolet rays absorbing particles from protruding from the surface of the ultraviolet rays cutting layer include making the content ratio of the ultraviolet rays absorbing particles in the ultraviolet rays cutting layer relatively small, allowing a coating film to stand for a predetermined period of time before curing when forming the ultraviolet rays cutting layer, and covering particle surfaces with a dispersant or the like to bring a surface energy of the particles close to a surface energy of a matrix component.

### (Transparent Base)

The transparent base has self-supporting properties, and various transparent bases can be used as long as they have transparency that allows the cover member to have an average transmittance of 85% or more at a wavelength of 400 nm to 800 nm. Specific examples thereof include a glass base and a resin base, and the glass base is preferred because of its excellent durability and scratch resistance, and a more suitable coefficient of thermal expansion.

Examples of a glass constituting the glass base include soda lime silicate glass, aluminosilicate glass, borate glass, lithium aluminosilicate glass, quartz glass, borosilicate glass, and alkali-free glass, and soda lime silicate glass and aluminosilicate glass are preferred because they are in relatively large demand and have excellent availability.

The glass base may be made of glass ceramic. The “glass ceramic” refers to an “amorphous glass” that is heat-treated to precipitate crystals, and contains crystals. The glass ceramic may contain two or more types of Li₃PO₄ crystal, Li₄SiO₄ crystal, Li₂SiO₃ crystal, Li₂Mg(SiO₄) crystal, LiAlSiO crystal, and Li₂Si₂O₄ crystal, or may contain any one type as a main crystal. Two or more types of solid solution crystals selected from the group consisting of Li₃PO₄, Li₄SiO₄, Li₂SiO₃, Li₂Mg(SiO₄) and Li₂Si₂O₄ may be used as the main crystals. A crystallization rate of the glass ceramic is preferably 5% or more, more preferably 10% or more, still more preferably 15% or more, and particularly preferably 20% or more to increase mechanical strength. An average grain size of precipitated crystals of the glass ceramic is preferably 5 nm or more, and particularly preferably 10 nm or more in order to increase strength. In order to increase the transparency, the average grain size is preferably 80 nm or less, more preferably 60 nm or less, still more preferably 50 nm or less, particularly preferably 40 nm or less, and most preferably 30 nm or less. The average grain size of the precipitated crystals is determined from a transmission electron microscope (TEM) image.

Examples of a resin constituting the resin base include fluororesin and polyimide resin.

When the transparent base is a glass base, a glass composition of the glass base preferably contains TiO₂ in an amount of 0.0% to 0.1%, and more preferably 0.0% to 0.02%, in terms of mass % based on oxides. TiO₂ is a component that, when contained in a predetermined amount in glass, can impart the ultraviolet rays cutting performance to the glass base. However, when the glass base contains a large amount of TiO₂, raw materials for the glass base may be expensive, or the glass composition may need to be specially adjusted to manufacture the glass. The cover member according to the present embodiment has an excellent ultraviolet rays cutting performance by including the ultraviolet rays cutting layer even without using such glass for the transparent base. Therefore, from the viewpoint of preparing a glass base at a lower cost or more easily, the content of TiO₂ is preferably within the range described above. Note that regarding the glass composition, when a lower limit value of a content of a certain component is 0 or 0.0, it means that the component may not be contained.

As TiO₂, CeO₂ is also a component that, when contained in a predetermined amount in glass, can impart the ultraviolet rays cutting performance to the glass base. Therefore, for the same reason as TiO₂, the glass base preferably contains CeO₂ in an amount of 0.0% to 0.1%, and more preferably 0.0% to 0.02%, in terms of mass % based on oxides.

In the case where the transparent base is a glass base, specific examples of preferable glass compositions include the following (i) to (vii). The glass compositions (i) to (vii) below are all in terms of mass % based on oxides. Glasses having the following glass compositions are commonly used for various purposes and are relatively easy to obtain and manufacture.
(i) A glass containing 65% to 70% of SiO₂, 3% to 8% of Al₂O₃, 12% to 17% of Na₂O, 0.2% to 0.6% of K₂O, 2% to 7% of MgO, 5% to 10% of CaO, 0.03% to 0.07% of TiO₂ and 0.05% to 0.1% of Fe₂O₃.
(ii) A glass containing 59% to 63% of SiO₂, 12% to 19% of Al₂O₃, 3% to 7% of MgO, 12% to 18% of Na₂O₃, 0% to 6% of K₂O and 0% to 5% of ZrO₂.
(iii) A glass containing 60% to 70% of SiO₂, 12% to 20% of Al₂O₃, 0% to 5% of MgO, 3% to 8% of Na₂O₃, 0% to 5% of K₂O, 2% to 7% of Li₂O and 0% to 5% of ZrO₂.
(iv) A glass containing 70% to 74% of SiO₂, 0% to 3% of Al₂O₃, 6% to 12% of CaO, 0% to 6% of MgO and 12% to 16% of Na₂O₃.
(v) A glass containing 59% to 63% of SiO₂, 12% to 19% of Al₂O₃, 3% to 7% of MgO, 12% to 18° % of Na₂O₃, 0% to 6% of K₂O and 0% to 5% of ZrO₂.
(vi) A glass containing 60% to 70% of SiO₂, 12% to 20% of Al₂O₃, 0% to 5% of MgO, 3% to 8% of Na₂O₃, 0% to 5% of K₂O, 2% to 7% of Li₂O and 0% to 5% of ZrO₂.
(vii) A glass containing 40% to 70% of SiO₂, 10% to 35% of Li₂O, 4% to 15% of Al₂O₃, 0.5% to 5% of P₂O₅, 0% to 5% of ZrO₂, 0% to 10% of B₂O₃, 0% to 3% of Na₂O, 0% to 2% of K₂O, 0% to 4% of SnO₂, and 0% to 10% of MgO.

Note that each of the above glasses (ii) to (vii) may contain a total of approximately 0% to 5% of TiO₂, Fe₂O₃, and CeO₂. In each glass, the content of TiO₂ is preferably 0.0% to 0.1%, and more preferably 0.0% to 0.02%. The content of CeO₂ is preferably 0.0% to 0.1%, and more preferably 0.0% to 0.02%.

A thickness of the transparent base is 0.2 mm or less. Accordingly, a weight of the cover member can be reduced. The thickness of the transparent base is more preferably 0.15 mm or less, and still more preferably 0.11 mm or less. A lower limit of the thickness is not particularly limited, and from the viewpoint of ensuring durability, it is preferably 0.05 mm or more.

Preferably, the first main surface of the transparent base has an uneven structure. In this way, adhesion between the ultraviolet rays cutting layer and the transparent base is improved, and shrinkage during film formation and peeling of the ultraviolet rays cutting layer due to heating at a high temperature or the like can be prevented. By increasing the adhesion between the ultraviolet rays cutting layer and the transparent base, it is also possible to make the film thickness of the ultraviolet rays cutting layer relatively large and further increase the ultraviolet rays cutting performance.

Specifically, in the uneven structure, it is preferable that a height difference measured by an atomic force microscope is 1 nm to 50 nm. The height difference measured by an atomic force microscope is preferably 1 nm or more and more preferably 5 nm or more, from the viewpoint of improving the adhesion. On the other hand, from the viewpoint of reducing scattering of incident light, the height difference measured by an atomic force microscope is preferably 50 nm or less, and more preferably 20 nm or less. The height difference measured by an atomic force microscope refers to an average value of three points excluding the largest value and the smallest value among the maximum height differences read using an atomic force microscope from 1 μm square shape images observed at five points on the first main surface before the ultraviolet rays cutting layer is formed.

In the uneven structure, a surface roughness Ra is preferably 0.3 nm to 3 nm. Ra is preferably 0.3 nm or more, and more preferably 0.5 nm or more from the viewpoint of improving adhesion. On the other hand, from the viewpoint of reducing scattering of incident light, Ra is preferably 3 nm or less, and more preferably 2 nm or less. Ra refers to an average value of three points excluding the largest value and the smallest value among arithmetic mean roughness calculated from 1 μm square shape images observed at five points on the first main surface before the ultraviolet rays cutting layer is formed using an atomic force microscope.

A method for providing the uneven structure on the first main surface is not particularly limited, and for example, when the transparent base is a glass base, a preferred method is to slim the first main surface of the glass base with hydrofluoric acid before the ultraviolet rays cutting layer is formed. Further, by slimming with hydrofluoric acid, the thickness of the glass base can be adjusted at the same time as providing the uneven structure.

The uneven structure of the first main surface can also be confirmed from the height difference of the uneven structure, which is determined by observing a cross section of the cover member cut along with the glass base with a scanning electron microscope after the ultraviolet rays cutting layer is formed. The height difference is preferably 1 nm or more, and more preferably 5 nm or more. The height difference is preferably 50 nm or less, and more preferably 20 nm or less. The height difference obtained by observing the cross section of the cover member with a scanning electron microscope refers to an average value of three points excluding the largest value and the smallest value among maximum height differences read from cross-sectional images observed at 1 μm width at 5 points.

### (Cover Member)

The cover member according to the present embodiment has a transmittance at a wavelength of 300 nm of 3% or less, preferably 2% or less, and more preferably 1.5% or less. Since the cover member has performance in cutting deep ultraviolet rays by having a transmittance of the above value at a wavelength of 300 nm, the solar cell can be protected when the cover member is used for a solar cell. The transmittance at a wavelength of 300 nm is preferably as small as possible, and may be 0%, but a practical lower limit is 0.01%.

The cover member according to the present embodiment has an average transmittance of 85% or more at a wavelength of 400 nm to 800 nm, preferably 88% or more, and more preferably 90% or more. Since the cover member can transmit light in the visible range satisfactorily by having an average transmittance of the above value at a wavelength of 400 nm to 800 nm, a sufficient power generation efficiency can be achieved when the cover member is used for a solar cell. The average transmittance at a wavelength of 400 nm to 800 nm is preferably as large as possible, and may be 100%, but a practical upper limit is 99%.

That is, the cover member according to the present embodiment has excellent performance in protecting the solar cell from deep ultraviolet rays, and can provide a sufficient power generation efficiency of the solar cell by having a transmittance of 3% or less at a wavelength of 300 nm and an average transmittance of 85% or more at a wavelength of 400 nm to 800 nm.

In addition, the cover member according to the present embodiment preferably has a transmittance of 80% or more at a wavelength of 400 nm, more preferably 85% or more, and still more preferably 90% or more. Since the cover member can transmit light in the visible range satisfactorily by having a transmittance of the above value at a wavelength of 400 nm, a more sufficient power generation efficiency can be achieved when the cover member is used for a solar cell. The transmittance at a wavelength of 400 nm is preferably as large as possible, and may be 100%, but a practical upper limit is 95%.

The cover member according to the present embodiment has the ultraviolet rays cutting performance, but when the transmittance at a wavelength of 300 nm is 3% or less and the average transmittance at a wavelength of 400 nm to 800 nm is 85% or more, the cover member may be one that selectively cuts deep ultraviolet rays among the ultraviolet rays, or may be one that cuts not only deep ultraviolet rays but also a range having a longer wavelength than deep ultraviolet rays (UV-A, UV-B). However, the relatively long wavelength range of ultraviolet rays can contribute to power generation of the solar cell along with the visible light. Therefore, from the viewpoint of increasing the power generation efficiency when used in a solar cell, the transmittance of the cover member at a wavelength of 350 nm is preferably 30% or more, more preferably 50% or more, and still more preferably 55% or more. The transmittance at a wavelength of 350 nm is preferably as large as possible, but considering the performance in cutting deep ultraviolet rays, a practical upper limit is approximately 70%. The transmittance at a wavelength of 350 nm may vary depending on the type of ultraviolet rays absorbing particles in the ultraviolet rays cutting layer. From the viewpoint of relatively increasing the transmittance at a wavelength of 350 nm, titanium oxide (TiO₂) nanoparticles, cerium oxide (CeO₂) nanoparticles and the like are preferable to be used as the ultraviolet rays absorbing particles.

A haze of the cover member according to the present embodiment is preferably 0.1% or more, more preferably 0.3% or more, and still more preferably 0.5% or more. When the haze is equal to or greater than the above value, components of particularly short wavelengths of the light incident on the cover member are slightly scattered in the cover member, and can be more efficiently absorbed by the ultraviolet rays absorbing particles. On the other hand, the haze is preferably 5% or less, more preferably 3% or less, and still more preferably 2% or less, in order to prevent scattering of visible light components of incident light and the decrease in the transmittance. The cover member may have a haze of 0.1% to 5%. The haze refers to a value measured by a haze meter.

A main surface of the cover member according to the present embodiment preferably has an area of 1 m² or more, more preferably 1.5 m² or more, and still more preferably 2 m² or more. A length of a long side of the main surface of the cover member is preferably 1.5 m or more, more preferably 2 m or more, and still more preferably 2.2 m or more. A length of a short side is preferably 0.5 m or more, and more preferably 0.7 m or more. More preferably, in the cover member, the area of the main surface is 1 m² or more, and the length of the long side is 1.5 m or more or the length of the short side is 0.5 m or more. Note that when the shape of the main surface is not rectangular, the long side and the short side of the main surface mean a long side and a short side of a rectangle circumscribed to the shape of the main surface, respectively.

In a solar cell to be mounted on an artificial satellite, there are cases where a cover member is required to have a relatively large main surface, whose area and side lengths are equal to or greater than the above values. As described above, the cover member according to the present embodiment can both be made thinner more easily and have transmission performance required for use in a solar cell with no need to prepare a glass having a special composition. Here, if a glass having a special composition is prepared with a relatively large main surface area, there may be cases where productivity is poor or manufacturing is difficult due to the cost of raw materials and the availability of manufacturing equipment. In contrast, in the present embodiment, a glass having a more general glass composition or the like can be used as the transparent base, and therefore it is easier to manufacture or obtain a glass with a larger main surface. In other words, the effects of the present invention are particularly advantageous when a glass sheet is difficult to obtain or manufacture in a case where a glass having a special glass composition is used, such as when a main surface of a cover member is relatively large.

### (Method for Manufacturing Cover Member)

A method for manufacturing the cover member according to the present embodiment is not particularly limited as long as the above-mentioned cover member can be obtained, and an example thereof includes a step of preparing a transparent base (preparation step) and a step of forming an ultraviolet rays cutting layer on the transparent base (film forming step).

### (Preparation Step)

In the preparation step, a transparent base having a thickness of 0.2 mm or less is prepared. As the transparent base, the various ones mentioned above can be used, and commercially available products may be used, or those manufactured from raw materials may be used.

In the preparation step, treatment such as polishing may be performed in order to make the thickness of the transparent base 0.2 mm or less. Treatment for providing an uneven structure on the first main surface of the transparent base may be performed.

When the transparent base is a glass base, examples of a method for adjusting the thickness thereof include physical polishing and chemical polishing, and chemical polishing is preferred from the viewpoint of providing an uneven structure on a surface of the transparent base. Among these, it is more preferable to slim the first main surface of the glass base with hydrofluoric acid in the preparation step. By performing such treatment, the thickness of the transparent base can be adjusted, and at the same time, an uneven structure can be formed on the first main surface.

A specific procedure for slimming with hydrofluoric acid is not particularly limited, and examples thereof include a method of transporting a glass base with a thickness of approximately 0.4 mm in a flat flow manner and applying hydrofluoric acid in a shower form from above and below, and a method of submerging a glass base in a hydrofluoric acid solution and shaking. In addition, examples of a method for forming an uneven structure on the main surface of the glass base include a method of forming unevenness by mixing KF or NH₄F with a hydrofluoric acid solution and generating reaction products on the glass surface, and a method of forming unevenness on the surface by sandblasting the glass base in advance and then etching the glass base. As mentioned above, from the viewpoint of preventing peeling of the ultraviolet rays cutting layer, it is preferable to provide the uneven structure on the first main surface, but the uneven structure may be provided on the second main surface within a range that does not impede the effects of the present invention. That is, the various kinds of treatment described above may be performed on one side or both sides of the transparent base.

### (Film Forming Step)

In the film forming step, the ultraviolet rays cutting layer is formed on the transparent base. Hereinafter, an example will be described in which the ultraviolet rays cutting layer has a structure containing ultraviolet rays absorbing particles in a matrix, and a main component of the matrix is SiO₂, and the ultraviolet rays absorbing particles are metal oxide nanoparticles.

The ultraviolet rays cutting layer may be formed by various known methods. As a film forming method, from the viewpoint of ease of forming a film on a relatively large transparent base, a method including preparing a liquid coating composition, applying the coating composition to a surface to be coated to form a coating film, and curing the coating film is preferred.

The matrix whose main component is SiO₂ can be formed by, for example, applying a matrix liquid containing a hydrolyzate (sol-gel silica) of a silane compound such as alkoxysilane to form a coating film, and heating the coating film to cure the coating film. Therefore, the ultraviolet rays cutting layer can be formed by preparing a coating composition in which such a matrix liquid further contains metal oxide nanoparticles, applying the coating composition to the surface to be coated, and curing the obtained coating film.

Such a coating composition can be produced by, for example, preparing a dispersion liquid in which metal oxide nanoparticles are dispersed in a dispersion medium and a matrix liquid containing a hydrolyzate (sol-gel silica) of a silane compound, and then mixing the two liquids.

The dispersion liquid is obtained by adding the metal oxide nanoparticles to the dispersion medium and stirring the mixture to disperse the metal oxide nanoparticles. As the metal oxide nanoparticles, those mentioned above can be used as appropriate. As the dispersion medium, known organic solvents, water, and the like can be used, and for example, alcohol solvents such as ethanol, methanol, and isopropyl alcohol, ketone solvents such as acetone and methyl ethyl ketone, and ester solvents such as methyl acetate, ethyl acetate, and butyl acetate are preferred, and two or more types may be used in combination. A stirring time is preferably, for example, 0.5 hours to 50 hours. The dispersion liquid may contain known additives such as a dispersant, a thickener, and an antifoaming agent.

The matrix liquid can be obtained by, for example, adding a silane compound and optionally an acid component, an alkali component, a metal complex, or the like as a catalyst to a solvent, and stirring at 10° C. to 60° C. for approximately 5 minutes to 300 minutes. As the silane compound, any known silane compound can be used as appropriate, and it is preferable to contain an alkoxysilane. These silane compounds may be used alone or in combination of two or more kinds thereof. Furthermore, known organic solvents, water, or the like can be used as the solvent, and alcoholic solvents such as ethanol, methanol, and isopropyl alcohol are preferable, and two or more types thereof may be used in combination. The matrix liquid may further contain additives such as a leveling agent.

The coating composition is obtained by mixing the dispersion liquid and the matrix liquid obtained in this way. A specific composition of the coating composition can be adjusted as appropriate depending on a desired film composition, and for example, the content of the metal oxide nanoparticles in the coating composition is preferably 0.1 mass % to 20 mass %, and more preferably 1 mass % to 5 mass %. The content of the silane compound and the hydrolyzate thereof in the coating composition is preferably 5 mass % to 40 mass %, and more preferably 10 mass % to 30 mass %. The content of the solvent (dispersion medium) in the coating composition is preferably 50 mass % to 99.9 mass %, and more preferably 70 mass % to 99.5 mass %.

Next, the coating composition is applied onto the surface to be coated, that is, the transparent base, to form the coating film. A coating method is not particularly limited, and can be appropriately selected from various wet coating methods such as spin coating, roller coating, spray coating, flow coating, bar coating, and die coating.

Next, the coating film is heated and cured. The heating may be performed by any known method, and is preferably performed at 50° C. to 600° C. for approximately 1 minute to 60 minutes.

Through the steps described above, the ultraviolet rays cutting layer can be formed, and then the cover member according to the present embodiment can be obtained. Note that the above method is an example, and changes may be made as appropriate within a range that does not impede the effects of the present invention.

The cover member according to the present embodiment is particularly suitably used as a cover member for a solar cell mounted on an artificial satellite.

### EXAMPLES

Hereinafter, the present invention will be described with reference to Examples, but the present invention is not limited thereto. Examples 1 to 4, 6, and 8 are working examples, and Examples 5, 7, and 9 are comparative examples.

(Evaluation) Evaluation of each example was performed by the following method.

### (Transmittance of Cover Member)

The transmittance of the cover member at wavelengths of 300 nm, 350 nm, and 400 nm, and the average transmittance at a wavelength of 400 nm to 800 nm were measured. Measurement was performed using a spectrophotometer (manufactured by Hitachi, Ltd., model U-4100). Note that the average transmittance at a wavelength of 400 nm to 800 nm was an average value of transmittances for every 5 nm from the wavelength 400 nm.

### (Haze of Cover Member)

The haze of the cover member was measured using a haze meter (Haze Guard Plus, manufactured by BYK Gardner).

### (Sheet Thickness of Transparent Base)

The sheet thickness of the transparent base takes an average value of five points measured using a micrometer (manufactured by Mitutoyo Corporation, model MDH-25 MB).

### (Uneven Structure of First Main Surface)

Regarding the first main surface of the transparent base before forming the ultraviolet rays cutting layer, the height difference and Ra (arithmetic mean roughness) of the uneven structure of the first main surface of the transparent base as measured by an atomic force microscope were determined by measurement using an atomic force microscope (manufactured by Seiko Instruments Inc., model SPA400) and analysis using analysis software (manufactured by Seiko Instruments Inc., Nanonavi). An arithmetic mean roughness from a surface shape image measured for 1 μm square in DFM mode is taken as Ra of the glass surface, and a value of the height difference read from the surface shape image was taken as the height difference of the glass surface unevenness. Of the maximum height difference or the arithmetic mean roughness read from 1 μm square shape images observed at 5 points, average values of three points excluding the largest value and the smallest value were used.

The height difference of the uneven structure of the first main surface of the transparent base, determined by observing with a scanning electron microscope, was determined as an average value of three points excluding the largest value and smallest value of maximum height differences read from a cross-sectional image obtained by observing a cross section after forming the ultraviolet rays cutting layer with a width of 1 μm at 5 points using a scanning electron microscope (manufactured by Hitachi High-Tech Corporation, S4800).

(TiO₂ Content and CeO₂ Content in Transparent Base)

TiO₂ content and CeO₂ content of the transparent base (glass base) without an ultraviolet rays cutting layer were measured using a scanning X-ray fluorescence spectrometer (manufactured by Rigaku Corporation, ZSX Primus IV).

### (Film Thickness of Ultraviolet Rays Cutting Layer)

The film thickness of the ultraviolet rays cutting layer was measured using a stylus type surface profile measuring device (manufactured by Veeco Instruments Inc., model Dectak 150). Specifically, a part of the ultraviolet rays cutting layer was peeled off with a knife to create a step, and a value of the step was measured using the above device and was defined as the film thickness of the ultraviolet rays cutting layer.

### (Evaluation of Peelability of Ultraviolet Rays Cutting Layer)

After the ultraviolet rays cutting layer was formed, whether the ultraviolet rays cutting layer had peeled off from the cover member was evaluated visually and using an optical microscope. Evaluation criteria were as follows.

Peeling: The ultraviolet rays cutting layer had peeled off and floating parts were observed.

No peeling: No peeling and floating parts of the ultraviolet rays cutting layer were observed.

### (200° C. Heat Resistance Test)

The cover member after the ultraviolet rays cutting layer was formed was held at 200° C. for 30 minutes, and then the peelability was evaluated in the same manner as the above-mentioned peelability evaluation.

Cover members of Examples 1 to 9 were produced according to the following procedure. In each example, the ultraviolet rays cutting layer was formed by the method of Production Example 1 or Production Example 2.

### Production Example 1: Formation of Ultraviolet Rays Cutting Layer Containing TiO₂ Nanoparticles

TiO₂ nanoparticles (manufactured by Sakai Chemical Industry Co., Ltd., STR-100N), a dispersant (manufactured by BYK, disperbyk2013), and a dispersion medium (manufactured by Japan Alcohol Trading CO., LTD., Solmix AP-1) were used as raw materials, and a dispersion liquid containing TiO₂ nanoparticles was prepared by putting the raw materials and zirconia beads with a diameter of 0.3 mm into a glass bottle and stirring for 10 hours with a paint shaker.

A matrix liquid was prepared by mixing TEOS (tetraethoxysilane) and GPTMS ((3-glycidyloxypropyl)trimethoxysilane) as silane compounds, nitric acid as a catalyst, water as a solvent, Solmix AP-1 (manufactured by Japan Alcohol Trading CO., LTD.), MeOH, and a leveling agent (manufactured by BYK, BYK307), and stirring at 50° C. for 60 minutes.

The obtained dispersion liquid and matrix liquid were mixed to obtain a coating composition for film formation.

After cleaning the first main surface of the transparent base with ozone, a coating film of the coating composition is formed on the first main surface by spin coating, and the coating film is cured by heating at 100° C. for 30 minutes to form the ultraviolet rays cutting layer containing TiO₂ nanoparticles. Note that each component was prepared so that the composition of the coating composition would be as shown in Table 1, and the film composition shown in Table 1 was obtained. The film thickness of the coating film was adjusted by adjusting an applying amount of the coating composition.

### Production Example 2: Formation of Ultraviolet Rays Cutting Layer Containing ZnO Nanoparticles

An ultraviolet rays cutting layer containing ZnO nanoparticles was formed in the same manner as in Production Example 1 except that TiO₂ nanoparticles were changed to ZnO nanoparticles (manufactured by Sakai Chemical Industry Co., Ltd., Finex-50), and the type of the dispersant was changed to disperbyk180 manufactured by Byk.

TABLE 1

| | | Ex. 1 | Ex. 2 | Ex. 3 | Ex. 4 | Ex. 5 | Ex. 6 | Ex. 7 | Ex. 8 |
|---|---|---|---|---|---|---|---|---|---|
| Coating | TEOS | 16.7% | 11.1% | 5.6% | 19.5% | 16.7% | 14.6% | 11.1% | 19.5% |
| composition | GPTMS | 2.8% | 1.9% | 0.9% | 3.2% | 2.8% | 0.6% | 1.9% | 3.2% |
| | ZnO nanoparticles | — | — | — | — | — | 5.0% | 5.0% | — |
| | (FINEX-50) | | | | | | | | |
| | Dispersant | — | — | — | — | — | 1.5% | 1.5% | — |
| | (DISPEBYK 180) | | | | | | | | |
| | TiO₂ nanoparticles | 2.5% | 5.0% | 2.5% | 1.3% | 2.5% | — | — | 1.3% |
| | (STR-100N) | | | | | | | | |
| | Dispersant | 0.8% | 1.5% | 0.8% | 0.4% | 0.8% | — | — | 0.4% |
| | (DISPERBYK2013) | | | | | | | | |
| | Leveling agent | 0.0% | 0.0% | 0.0% | 0.1% | 0.0% | 0.0% | 0.0% | 0.1% |
| | (BYK307) | | | | | | | | |
| | Solvent/dispersion | 63.5% | 71.4% | 85.7% | 59.6% | 63.5% | 68.3% | 71.4% | 59.6% |
| | medium (AP-1) | | | | | | | | |
| | MeOH | 6.7% | 4.4% | 2.2% | 7.8% | 6.7% | 4.4% | 4.4% | 7.8% |
| | Nitric acid | 0.4% | 0.3% | 0.1% | 0.5% | 0.4% | 0.3% | 0.3% | 0.5% |
| | Water | 6.6% | 4.4% | 2.2% | 7.7% | 6.6% | 5.2% | 4.4% | 7.7% |
| | Total | 100.0% | 100.0% | 100.0% | 100.0% | 100.0% | 100.0% | 100.0% | 100.0% |
| Ultraviolet | TEOS-derived cured | 45.0% | 28.0% | 28.0% | 54.4% | 45.0% | 37.3% | 28.0% | 54.4% |
| rays | product | | | | | | | | |
| cutting | GPTMS-derived | 24.3% | 15.1% | 15.1% | 29.3% | 24.3% | 5.1% | 15.1% | 29.3% |
| layer | cured product | | | | | | | | |
| | ZnO nanoparticles | — | — | — | — | — | 44.1% | 43.5% | — |
| | (FINEX-50) | | | | | | | | |
| | Dispersant | — | — | — | — | — | 13.2% | 13.1% | — |
| | (DISPEBYK180) | | | | | | | | |
| | Leveling agent | 0.4% | 0.3% | 0.3% | 0.5% | 0.4% | 0.3% | 0.3% | 0.5% |
| | (BYK307) | | | | | | | | |
| | TiO₂ nanoparticles | 23.3% | 43.5% | 43.5% | 12.1% | 23.3% | — | — | 12.1% |
| | (STR-100N) | | | | | | | | |
| | Dispersant | 7.0% | 13.1% | 13.1% | 3.6% | 7.0% | — | — | 3.6% |
| | (DISPERBYK2013) | | | | | | | | |
| | Total | 100.0% | 100.0% | 100.0% | 100.0% | 100.0% | 100.0% | 100.0% | 100.0% |

### Example 1 to Example 7

A commercially available glass (manufactured by AGC Inc., commonly known as AS2) with a thickness of 0.4 mm was prepared. Slimming treatment was performed by submerging this glass in a hydrofluoric acid solution and shaking to obtain a glass base whose thickness was adjusted to 0.1 mm. This glass was used as the transparent base. Table 2 shows values of Ra and height difference of the uneven structure of the first main surface of the glass base.

Next, an ultraviolet rays cutting layer was formed on the glass base. In Examples 1 to 5, the ultraviolet rays cutting layer was formed using the method of Production Example 1, and in Examples 6 and 7, the ultraviolet rays cutting layer was formed using the method of Production Example 2. In this way, the cover members of Examples 1 to 7 were obtained.

### Example 8

A smooth glass base whose thickness was adjusted to 0.1 mm by polishing was used as the transparent base. Table 2 shows values of Ra and height difference of the uneven structure of the first main surface of the glass base. An ultraviolet rays cutting layer was formed on this glass base by the method of Production Example 1 to obtain the cover member of Example 8.

### Example 9

A glass base having a TiO₂ content and a CeO₂ content of values shown in Table 2 was used as the transparent base. The prepared transparent base was used as the cover member of Example 9 without forming an ultraviolet rays cutting layer.

Table 2 shows physical properties and evaluation results of the cover members of each example.

TABLE 2

| | | Ex. 1 | Ex. 2 | Ex. 3 | Ex. 4 | Ex. 5 | Ex. 6 | Ex. 7 | Ex. 8 | Ex. 9 |
|---|---|---|---|---|---|---|---|---|---|---|
| Cover | Transmittance [%] at | 1.4 | 0.1 | 2.8 | 1.5 | 9.2 | 0.5 | 5.0 | 1.4 | 1.7 |
| member | wavelength of 300 nm | | | | | | | | | |
| | Transmittance [%] at | 55.0 | 40.5 | 60.3 | 56.5 | 71.1 | 0.7 | 7.0 | 55.7 | 78.6 |
| | wavelength of 350 nm | | | | | | | | | |
| | Transmittance [%] at | 86.8 | 85.3 | 85.7 | 89.4 | 87.7 | 81.4 | 87.0 | 89.0 | 90.4 |
| | wavelength of 400 nm | | | | | | | | | |
| | Average transmittance | 90.3 | 88.2 | 88.4 | 90.5 | 91.0 | 88.6 | 90.3 | 90.5 | 91.0 |
| | [%] at wavelength of 400 | | | | | | | | | |
| | nm to 800 nm | | | | | | | | | |
| | Haze [%] | 0.25 | 0.34 | 0.26 | 0.31 | 0.27 | 1.03 | 0.72 | 0.31 | 0.00 |
| Transparent | Sheet Thickness [mm] | 0.1 | 0.1 | 0.1 | 0.1 | 0.1 | 0.1 | 0.1 | 0.1 | 0.1 |
| base | Ra [nm] of first main | 0.86 | 0.86 | 0.86 | 0.86 | 0.86 | 1.03 | 0.86 | 0.16 | 1.7 |
| | surface | | | | | | | | | |
| | Height difference [nm] of | 11 | 11 | 10 | 10 | 11 | 10 | 10 | 1 | — |
| | first main surface (atomic | | | | | | | | | |
| | force microscope) | | | | | | | | | |
| | Height difference [nm] of | 12 | 14 | 14 | 11 | 12 | 16 | 15 | 0 | — |
| | first main surface | | | | | | | | | |
| | (scanning electron | | | | | | | | | |
| | microscope) | | | | | | | | | |
| | TiO₂ content [wt %] | 0.03 to | 0.03 to | 0.03 to | 0.03 to | 0.03 to | 0.03 to | 0.03 to | 0.03 to | 0.5 to |
| | | 0.07 | 0.07 | 0.07 | 0.07 | 0.07 | 0.07 | 0.07 | 0.07 | 1 |
| | CeO₂ content [wt %] | 0.01 or | 0.01 or | 0.01 or | 0.01 or | 0.01 or | 0.01 or | 0.01 or | 0.01 or | 0.3 to |
| | | less | less | less | less | less | less | less | less | 0.5 |
| Ultraviolet | Type of metal oxide | TiO₂ | TiO₂ | TiO₂ | TiO₂ | TiO₂ | ZnO | ZnO | TiO₂ | — |
| rays | nanoparticles | | | | | | | | | |
| cutting | Metal oxide nanoparticles | 23.1 | 43.5 | 43.5 | 12.1 | 12.1 | 43.5 | 43.5 | 12.1 | — |
| layer | content [wt %] | | | | | | | | | |
| | SiO₂ content [wt %] | 52.7 | 32.8 | 32.8 | 63.7 | 63.7 | 32.8 | 32.8 | 63.7 | — |
| | Film Thickness [μm] | 0.6 | 0.6 | 0.25 | 1.3 | 0.6 | 2.4 | 1.7 | 1.3 | — |
| | Presence or absence of | absent | absent | absent | absent | absent | absent | absent | absent | — |
| | peeling immediately after | | | | | | | | | |
| | film formation | | | | | | | | | |
| | Presence or absence of | absent | absent | absent | absent | absent | absent | absent | Present | — |
| | peeling after 200° C. heat | | | | | | | | | |
| | resistance test | | | | | | | | | |

The cover members of Examples 11 to 4, 6, and 8 could both be made thinner and have desired transmission performance with no need to prepare a glass having a special composition. That is, while the thickness of the transparent base was 0.2 mm or less, the cover member had the performance in cutting deep ultraviolet rays and satisfactorily transmitted light in the visible range. In Examples 1 to 4 and 6, the first main surface of the transparent base had an appropriate uneven structure, so that peeling of the ultraviolet rays cutting layer could be prevented both immediately after film formation and after high-temperature heating.

As described above, the following matters are disclosed in the present specification.
1. A cover member to be used for a solar cell mounted on an artificial satellite, the cover member including:
   a transparent base; and
   an ultraviolet rays cutting layer disposed on the transparent base, in which
   the transparent base has a thickness of 0.2 mm or less, and
   the cover member has a transmittance of 3% or less at a wavelength of 300 nm, and an average transmittance of 85% or more at a wavelength of 400 nm to 800 nm.
2. A cover member to be used for a solar cell, the cover member including:
   a transparent base; and
   an ultraviolet rays cutting layer disposed on the transparent base, in which
   the transparent base has a thickness of 0.2 mm or less, and
   the cover member has a transmittance of 3% or less at a wavelength of 300 nm, and an average transmittance of 85% or more at a wavelength of 400 nm to 800 nm.
3. The cover member according to 1 or 2, in which
   the ultraviolet rays cutting layer includes SiO₂ and metal oxide nanoparticles, and
   a metal oxide constituting the metal oxide nanoparticles is one or more selected from the group consisting of zinc oxide, titanium oxide, cerium oxide, iron oxide, and tungsten oxide.
4. The cover member according to 3, in which
   the ultraviolet rays cutting layer includes 10 mass % to 50 mass % of the metal oxide nanoparticles and 20 mass % to 70 mass % of SiO₂, and has a film thickness of 0.2 μm to 2 μm.
5. The cover member according to any one of 1 to 4, in which
   the transparent base has a first main surface and a second main surface facing each other,
   the ultraviolet rays cutting layer is disposed on the first main surface of the transparent base, and
   the first main surface has an uneven structure with a height difference of 1 nm to 50 nm and a surface roughness Ra of 0.3 nm to 3 nm which are measured by an atomic force microscope.
6. The cover member according to any one of 1 to 5, in which
   the transparent base has a first main surface and a second main surface facing each other,
   the ultraviolet rays cutting layer is disposed on the first main surface of the transparent base, and
   the first main surface has an uneven structure with a height difference of 1 nm to 50 nm determined by observing a cross section of the cover member by a scanning electron microscope.
7. The cover member according to any one of 1 to 6, in which
   the transparent base is a glass base.
8. The cover member according to 7, in which
   the glass base includes, in terms of mass % based on oxides,
      0.0% to 0.10% of TiO₂, and
      0.0% to 0.1% of CeO₂.
9. The cover member according to 7, in which
   the glass base includes, in terms of mass % based on oxides,
      0.0% to 0.1% of TiO₂.
10. The cover member according to 7, in which
   the glass base includes, in terms of mass % based on oxides,
      0.0% to 0.10% of CeO₂.
11. The cover member according to any one of 1 to 10, in which
   the ultraviolet rays cutting layer has a refractive index of 1.5 to 1.8.
12. The cover member according to any one of 1 to 11, having a transmittance of 30% or more at a wavelength of 350 nm.
13. The cover member according to any one of 1 to 12, in which
   an area of a main surface is 1 m² or more, and a length of a long side is 1.5 m or more or a length of a short side is 0.5 m or more.
14. A solar cell to be mounted on an artificial satellite, the solar cell including the cover member according to any one of 1 to 13.

Although the present invention has been described in detail with reference to specific embodiments, it is apparent to those skilled in the art that various changes and modifications can be made without departing from the spirit and scope of the present invention. The present application is based on a Japanese Patent Application (No. 2021-208665) filed on Dec. 22, 2021, the contents of which are incorporated herein by reference.

### REFERENCE SIGNS LIST

10 cover member
1 transparent base
1a first main surface
1b second main surface
2 ultraviolet rays cutting layer
21 matrix
22 ultraviolet rays absorbing particles

1. A cover member to be used for a solar cell mounted on an artificial satellite, the cover member comprising:
a transparent base; and
an ultraviolet rays cutting layer disposed on the transparent base, wherein
the transparent base has a thickness of 0.2 mm or less, and
the cover member has a transmittance of 3% or less at a wavelength of 300 nm, and an average transmittance of 85% or more at a wavelength of 400 nm to 800 nm.

2. A cover member to be used for a solar cell, the cover member comprising:
a transparent base; and
an ultraviolet rays cutting layer disposed on the transparent base, wherein
the transparent base has a thickness of 0.2 mm or less, and
the cover member has a transmittance of 3% or less at a wavelength of 300 nm, and an average transmittance of 85% or more at a wavelength of 400 nm to 800 nm.

3. The cover member according to claim 1, wherein
the ultraviolet rays cutting layer comprises SiO₂ and metal oxide nanoparticles, and
a metal oxide constituting the metal oxide nanoparticles is one or more selected from the group consisting of zinc oxide, titanium oxide, cerium oxide, iron oxide, and tungsten oxide.

4. The cover member according to claim 3, wherein
the ultraviolet rays cutting layer comprises 10 mass % to 50 mass % of the metal oxide nanoparticles and 20 mass % to 70 mass % of SiO₂, and has a film thickness of 0.2 μm to 2 μm.

5. The cover member according to claim 1, wherein
the transparent base has a first main surface and a second main surface facing each other,
the ultraviolet rays cutting layer is disposed on the first main surface of the transparent base, and
the first main surface has an uneven structure with a height difference of 1 nm to 50 nm and a surface roughness Ra of 0.3 nm to 3 nm which are measured by an atomic force microscope.

6. The cover member according to claim 1, wherein
the transparent base has a first main surface and a second main surface facing each other,
the ultraviolet rays cutting layer is disposed on the first main surface of the transparent base, and
the first main surface has an uneven structure with a height difference of 1 nm to 50 nm determined by observing a cross section of the cover member by a scanning electron microscope.

7. The cover member according to claim 1, wherein
the transparent base is a glass base.

8. The cover member according to claim 7, wherein
the glass base comprises, in terms of mass % based on oxides,
0.0% to 0.1% of TiO₂, and
0.0% to 0.1% of CeO₂.

9. The cover member according to claim 7, wherein
the glass base comprises, in terms of mass % based on oxides,
0.0% to 0.1% of TiO₂.

10. The cover member according to claim 7, wherein
the glass base comprises, in terms of mass % based on oxides,
0.0% to 0.1% of CeO₂.

11. The cover member according to claim 1, wherein
the ultraviolet rays cutting layer has a refractive index of 1.5 to 1.8.

12. The cover member according to claim 1, having a transmittance of 30% or more at a wavelength of 350 nm.

13. The cover member according to claim 1, wherein
an area of a main surface is 1 m² or more, and a length of a long side is 1.5 m or more or a length of a short side is 0.5 m or more.

14. A solar cell to be mounted on an artificial satellite, the solar cell comprising the cover member according to claim 1.
